(19) United States
(12) Patent Application Publication
(10) Pub. No.: US 2013/0115757 A1
(43) Pub. Date: May 9, 2013

(54) METHOD FOR SEPARATING A PLURALITY OF DIES AND A PROCESSING DEVICE FOR SEPARATING A PLURALITY OF DIES

(71) Applicants: Manfred Engelhardt, Villach-Landskron (AT); Petra Fischer, Wernberg (AT)

(72) Inventors: Manfred Engelhardt, Villach-Landskron (AT); Petra Fischer, Wernberg (AT)

(73) Assignee: INFINEON TECHNOLOGIES AG, Neubiberg (DE)

(21) Appl. No.: 13/290,197

(22) Filed: Nov. 7, 2011

(51) Int. Cl. H01L 21/78; C23F 1/08

(52) U.S. Cl. 438/464; 156/345.24; 257/E21.599

(57) ABSTRACT

A method for separating a plurality of dies is provided, the method including: defining one or more portions to be removed from a carrier including a plurality of dies by chemically changing the properties of the one or more portions to be removed located between the dies; performing a front-end-of-line FEOL process on at least one die to form at least one semiconductor device; and selectively removing the one or more portions of the carrier whose properties were chemically changed for separating the dies along the removed one or more portions.

### TECHNICAL FIELD

Various embodiments relate generally to a method for separating a plurality of dies and a processing device for separating a plurality of dies.

### BACKGROUND

Currently, mechanical sawing is used for the separation of semiconductor chips, such as in the wafer dicing of silicon carbide SiC based products, e.g. SiC based chips, e.g. SiC based dies, e.g. chips manufactured on SiC or SiC substrates. The current approach results in extremely high processing costs. Mechanical sawing of SiC may result in damages, e.g. crack formation, which may negatively impact performance and yield. Furthermore, the sawing process is extremely expensive and may impact the quality or even the functionality of the chip. To reduce processing costs and to improve the quality of dies, a novel approach for chip separation of SiC-based chips is proposed.

### SUMMARY

Various embodiments provide a method for separating a plurality of dies. The method may include defining one or more portions to be removed from a carrier including a plurality of dies by chemically changing the properties of the one or more portions to be removed located between the dies; performing a front-end-of-line process on at least one die to form at least one semiconductor device; and selectively removing the one or more portions of the carrier whose properties were chemically changed for separating the dies along the removed one or more portions.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a method for separating a plurality of dies according to an embodiment;

FIGS. 2A to 2J show a method for separating a plurality of dies according to an embodiment;

FIGS. 3A to 3C show a method for separating a plurality of dies according to an embodiment;

FIG. 4 shows a processing device for separating a plurality of dies according to an embodiment.

### DETAILED DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

The word “over”, used herein to describe forming a feature, e.g. a layer, “over” a side or surface, may be used to mean that the feature, e.g. the layer may be formed “directly on”, e.g. in direct contact with, the implied side or surface. The word “over”, used herein to describe forming a feature, e.g. a layer “over” a side or surface, may be used to mean that the feature, e.g. the layer may be formed “indirectly on” the implied side or surface with one or more additional layers being arranged between the implied side or surface and the formed layer.

Various embodiments relate to an approach to separate chips, e.g. silicon chips, e.g. silicon carbide chips, e.g. chips based on SiC technology. Chip separation may be carried out based on unit processes, e.g. deposition processes, wet chemical etching, electrochemical processes, and plasma etch processes, which avoid crack formation.

Whilst kerf regions are destroyed, e.g. sawed through, during conventional mechanical sawing processes, various embodiments relate to chemically changing kerf regions, and selectively removing the kerf regions, whose properties were chemically changed for separating the dies, without mechanically sawing the kerf regions.

Various embodiments relate to an approach for separating SiC substrates, based on electrochemical etching i.e. the electrochemical separation of SiC, of portions between dies.

Various embodiments relate to the application of electrochemical etching of SiC for chip separation to replace the mechanical sawing process, thus eliminating mechanical sawing damage.

Various embodiments provide a novel approach for separating dies, which defines portions of the die and chemically changes kerf regions for selective removal, before the completion of front-end-of-line processes; thus the process differs from conventional wafer dicing processes wherein die separation is the carried out after all front-end-of-line processes are completed.

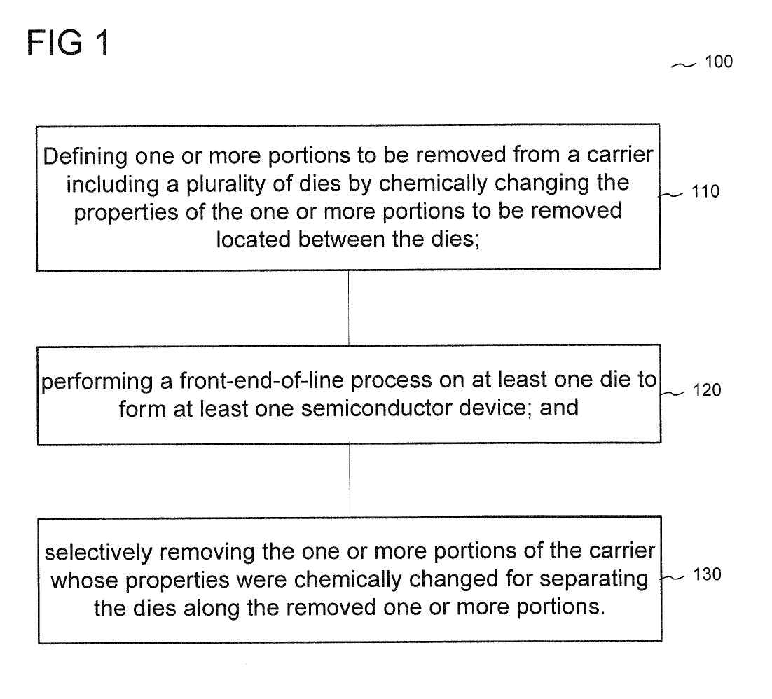

FIG. 1A shows a method for separating a plurality of dies according to an embodiment.

The method includes: defining one or more portions to be removed from a carrier including a plurality of dies by chemically changing the properties of the one or more portions to be removed located between the dies (in 110); performing a front-end-of-line FEOL process on at least one die to form at least one semiconductor device (in 120); and selectively removing the one or more portions of the carrier whose properties were chemically changed for separating the dies along the removed one or more portions (in 130).

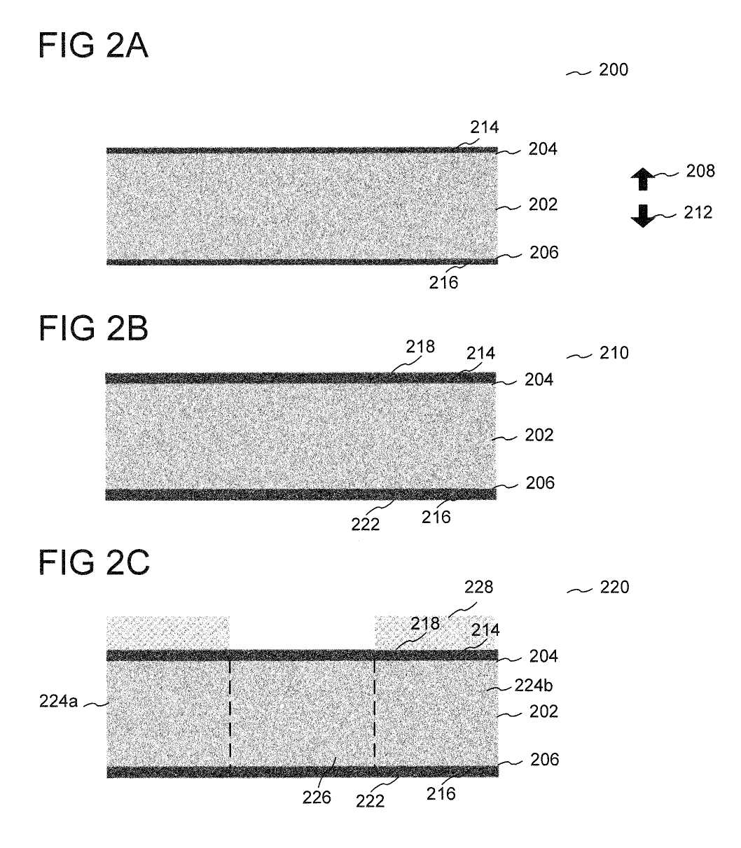

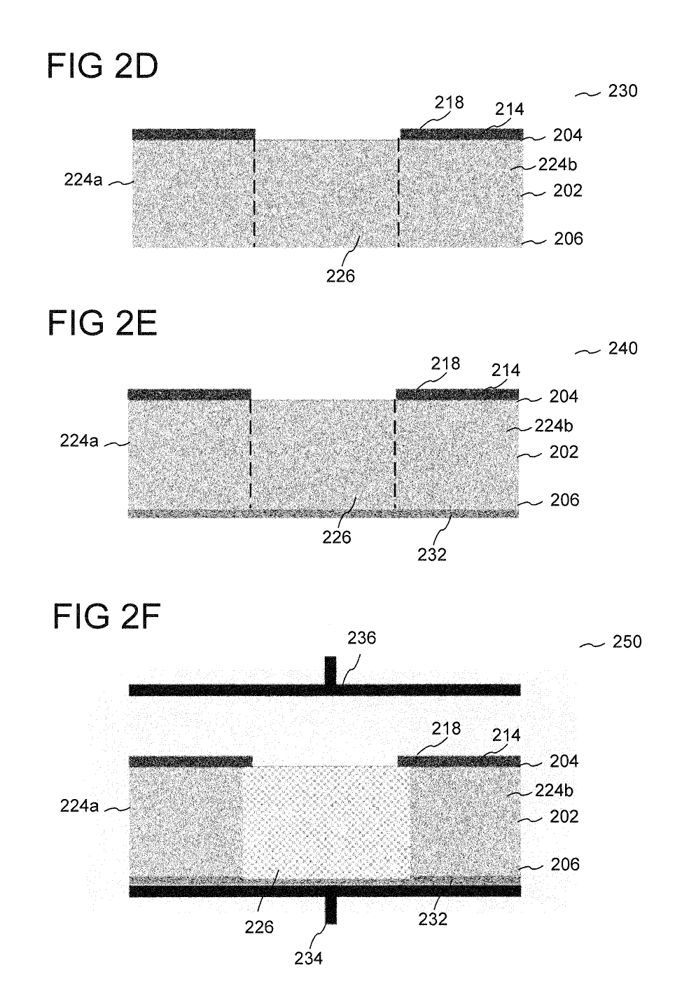

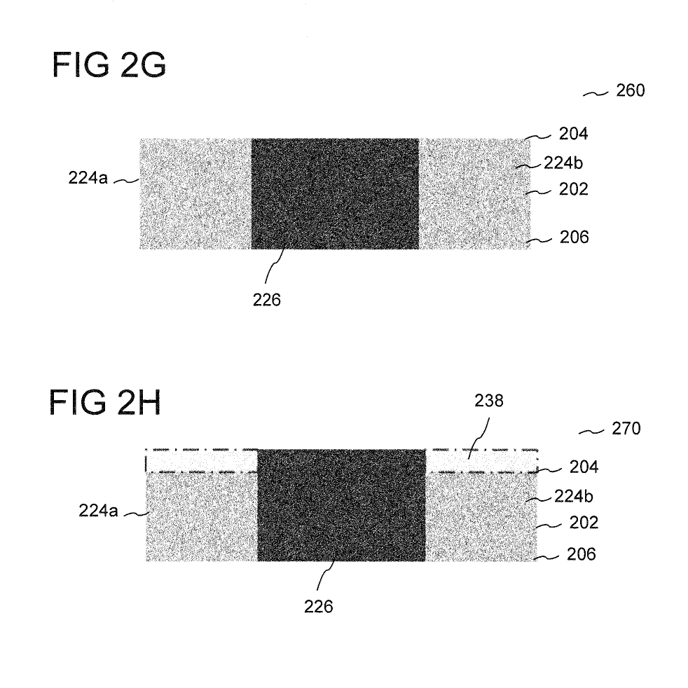

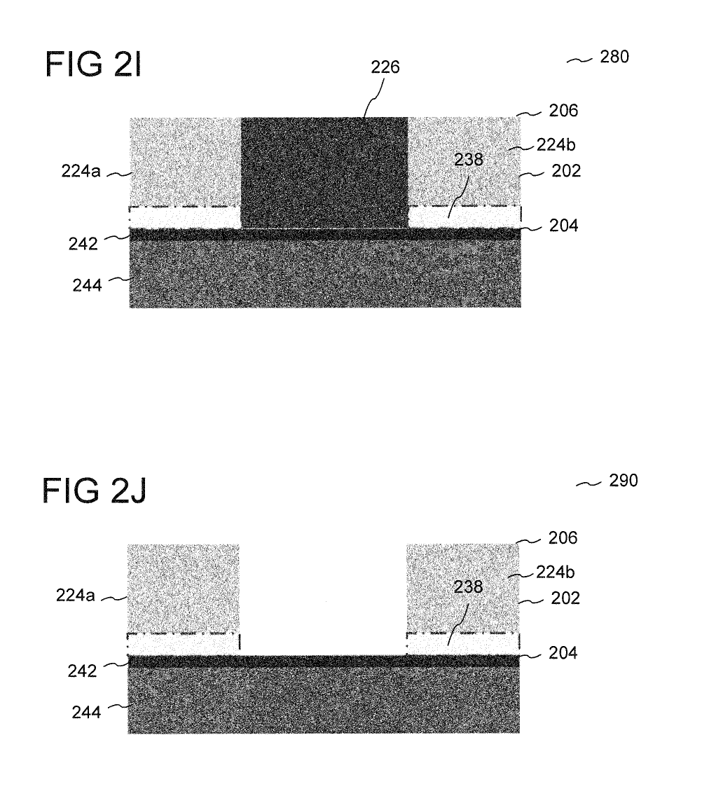

FIGS. 2A to 2J show a method for separating a plurality of dies according to an embodiment.

Carrier 202 may include a semiconductor wafer, e.g. a semiconductor substrate, e.g. a semiconductor substrate. Carrier 202 may include silicon. Carrier 202 may include silicon carbide. Carrier 202 may include a plurality of dies, wherein the plurality of dies may be formed within carrier 202. Carrier 202 may include a first carrier side 204 and a second carrier side 206, wherein first carrier side 204 may be configured to face a direction 208 opposite to a direction 212 which second carrier side 206 faces.

In FIG. 2A, first layer 214, e.g. an auxiliary first layer 214, may be formed over first carrier side 204. First layer 214 may be formed over, e.g. directly on, first carrier side 204. Second layer 216, e.g. an auxiliary second layer 216, may be formed over second carrier side 206. Second layer 216 may be formed over, e.g. directly on, second carrier side 206. First layer 214 and second layer 216 may be formed, e.g. deposited, in a single step. First layer 214 may be deposited, e.g. grown over first carrier side 204. Second layer 216 may be deposited, e.g. grown over second carrier side 206. First layer 214 and second layer 216 may include the same material. First layer 214 and second layer 216 may include different materials. First layer 214 and second layer 216 may include silicon dioxide SiO₂. First layer 214 and second layer 216 may be deposited by various deposition techniques, e.g. chemical vapor deposition of silicon dioxide, e.g. sputtering, e.g. thermal oxidation.

In FIG. 2B, third layer 218, e.g. an auxiliary third layer 218, may be formed over first carrier side 204. Third layer 218 may be formed over, e.g. directly on, first layer 214. Fourth layer 222, e.g. an auxiliary fourth layer 222, may be formed over second carrier side 206. Fourth layer 222 may be formed over, e.g. directly on, second layer 216. Third layer 218 and fourth layer 222 may be formed in a single step. Third layer 218 may be deposited, e.g. grown, directly on first layer 214. Fourth layer 222 may be deposited, e.g. grown, directly on second layer 216. Third layer 218 and fourth layer 222 may include the same material. Third layer 218 and fourth layer 222 may include polysilicon.

Carrier 202 may include a plurality of dies 224a, 224b. Two dies 224a, 224b are shown in the figures, however, the plurality of dies is not limited to two but may include one or more dies, e.g. three, four, five, six, seven, eight, nine, ten or even more dies such as tens or hundreds of dies. Each die 224a, 224b may be defined by a length×breadth dimension, e.g. each die 224a, 224b may include a 200 μm×200 μm die, e.g. each die 224a, 224b may include a 300 μm×300 μm die. One or more portions to be removed 226 from carrier 202 may be defined by chemically changing the properties of the one or more portions to be removed 226. The one or more portions to be removed 226 may be located between the dies 224a, 224b.

In FIG. 2C, masking layer 228, which may include a photoresist layer, may be formed over first carrier side 204. Masking layer 228 may be formed over first carrier side 204, e.g. photoresist layer 228 may be formed directly on third layer 218, e.g. photoresist layer 228 may be formed over first layer 214.

Masking layer 228 may be configured to allow the one or more portions 226 to be chemically changed and to shield dies 224a, 224b from being chemically changed. The properties of the one or more portions to be removed 226 located between dies 224a, 224b may be chemically changed, whereas dies 224a, 224b may be shielded from being chemically changed. Masking layer 228 may be configured to allow portions of first layer 214 and third layer 218 formed over one or more portions 226 to be removed and to shield portions of first layer 214 and third layer 218 formed over dies 224a, 224b from being removed.

Masking layer 228 may be processed using photolithography to form an etch mask, which exposes the portions of third layer 218 formed over one or more portions 226, to a following etch step, and which protects the portions of third layer 218 formed over plurality of dies 224a, 224b, from a following etch step.

Portions of third layer 218 formed over one or more portions 226 may be removed. Fourth layer 222 formed over second carrier side 206 may be removed. Etching, e.g. plasma etching, e.g. chemical etching, may be carried out to removed portions of third layer 218 formed over one or more portions 226 and fourth layer 222 formed over second carrier side 206.

Masking layer 228 may form an etch mask, which exposes the portions of first layer 214 formed over one or more portions 226, to a following etch step, and which protects the portions of first layer 214 formed over plurality of dies 224a, 224b, from a following etch step.

Portions of first layer 214 formed over one or more portions 226 may be removed. Second layer 216 formed over second carrier side 206 may be removed. Etching, e.g. plasma etching, e.g. chemical etching, may be carried out to removed portions of first layer 214 formed over one or more portions 226 and second layer 216 formed over second carrier side 206. Etching of third layer 218, first layer 214, second layer 216 and fourth layer 222 may be carried out in a single step or in separate etching steps.

In FIG. 2D, after removal of portions of third layer 218 and first layer 214 formed over first carrier side 204, and second layer 216 and fourth layer 222 formed over second carrier side 206, masking layer 228 may be removed, e.g. chemically removed, e.g. chemically dissolved. Portions of first layer 214 and third layer 218 may remain over plurality of dies 224a, 224b of carrier 202.

The properties of the one or more portions to be removed 226 may be chemically changed, e.g. electrochemically changed. The properties of one or more portions to be removed 226 may be chemically changed by an etching process, e.g. electrochemically etching the one or more portions to be removed 226 in an electrolyte solution.

In FIG. 2E, an electrically conductive layer 232, e.g. an electrically conductive layer including nickel, may be deposited over, e.g. directly on, second carrier side 206. Electrically conductive layer 232 may serve as an electrode. Electrically conductive layer 232 may include a metal, a metal compound, a metal alloy. Wherein electrically conductive layer 232 may include at least one of copper and iron, e.g. compounds including at least one of copper and iron, e.g. alloys including at least one of copper and iron, then deposition of a diffusion bather, e.g. Ti, e.g. TiN, e.g. Ta, e.g. TaN, over side 206, may be carried out, prior to the deposition of electrically conductive layer 232. The diffusion bather may be deposited between side 206 and electrically conductive layer 232 e.g. directly on side 206, to prevent the diffusion of at least one of copper and iron, into side 206.

Chemically changing the properties of the one or more portions to be removed 226 may include electrochemically converting the one or more portions to be removed into a porous material.

In FIG. 2F, electrochemical etching in an electrolyte, e.g. electrochemical etching in hydrofluoric acid HF, may be carried out, thereby chemically changing the exposed one or more portions 226, to porous silicon carbide SiC by anodization. The one or more portions 226 may be exposed to an electrolyte solution on first carrier side 204. A current, e.g. an electrical current, may be applied through the electrolyte solution between a counter electrode 236 located in the electrolyte solution and a further electrode, e.g. working electrode 234. Working electrode 234 may be electrically connected to the one or more portions to be removed 226 via a second carrier side 206.

Working electrode 234 may be positioned on second carrier side 206. Working electrode 234 may be electrically contacted to electrically conductive layer 232 formed on second carrier side 206. Counter electrode 236 may be positioned by the first carrier side 204, such that carrier 202 lies between working electrode 234 and counter electrode 236. One or more portions to be removed 226 from carrier 202 may be defined by chemically changing the properties of the one or more portions to be removed 226 located between the dies 224a, 224b, e.g. changing one or more portions 226 from silicon carbide to porous silicon carbide using the anodization process.

At least one of the first carrier side 204 and second carrier side 206 may include a front side or back side of a semiconductor wafer. A front side of a semiconductor wafer may include the side of the semiconductor wafer wherein a semiconductor device, e.g. an active device, may be formed. First carrier side 204 may include a semiconductor wafer front side. Second carrier side 206 may include a semiconductor wafer back side.

One or more portions 226 extending through a full height of carrier 202 from first carrier side 204 to second carrier side 206 may be chemically changed, e.g. from silicon carbide to porous silicon carbide. If one or more portions 226 extending through a full height of carrier 202 from first carrier side 204 to second carrier side 206 is chemically changed to porous SiC, i.e. SiC is formed throughout the full height of carrier 202 from first carrier side 204 to second carrier side 206, backside grinding i.e. grinding of second carrier side 206 is avoided later in the backend process.

If one or more portions 226 chemically changed to porous SiC may not extend through a full height of carrier 202 from first carrier side 204 to second carrier side 206 i.e. porous SiC is not formed throughout the full height of carrier 202 from first carrier side 204 to second carrier side 206, backside grinding i.e. grinding of second carrier side 206, may be carried out later in the backend process.

In FIG. 2G, first layer 214 and third layer 218 remaining over plurality of dies 224a, 224b of carrier 202 may be removed, e.g. chemically removed, e.g. etched. Electrically conductive layer 232 may be removed, e.g. chemically removed, e.g. etched. One or more portions to be removed 226 may be thermally oxidized into an oxide material. The properties of one or more portions 226 may be further chemically changed by chemically changing one or more portions 226 from porous silicon carbide to silicon dioxide, e.g. by the thermal oxidation of porous silicon carbide SiC resulting in silicon dioxide SiO₂.

In FIG. 2H, a front-end-of-line FEOL process may be performed on at least one die 224a, 224b to form at least one semiconductor device 238, e.g. a diode, e.g. a transistor, e.g. a bipolar junction transistor, e.g. a field effect transistor, e.g. a resistor, e.g. a capacitor, e.g. an inductor, e.g. a thyristor. A front-end-of-line FEOL process includes at least one process used to form the active electrical components of the semiconductor device. A front-end-of-line FEOL process includes performing a front-end-of-line FEOL process on a front side of a semiconductor wafer.

In current dicing methods, all front-end-of-line processes are completed, before defining portions of the wafer for dicing, i.e. before mechanical sawing takes place. According to various embodiments, the wafer, e.g. carrier 202, is defined into die areas 224a, 224b, and portions to be removed are chemically changed for separating the dies 224a 224b, before the front-end-of-line processes are completed.

Carrier 202 may be mounted over a support before selectively removing the one or more portions 226 of carrier 202 whose properties were chemically changed for separating the dies 224a, 224b along the removed one or more portions 226.

In FIG. 2I, carrier 202 may be mounted onto a supporting material 242, e.g. an adhesive tape, e.g. a foil. First carrier side 204 may be placed over supporting material 242, such that supporting material 242 may hold carrier 202. Supporting material 242 may hold dies 224a, 224b from a first carrier side 204 when separated. Supporting material 242 may be additionally supported by further supporting material 244, which may include a platform.

In FIG. 2J, one or more portions 226 of carrier 202 whose properties were chemically changed may be selectively removed for separating the dies along the removed one or more portions 226. One or more portions 226 may be selectively removed by etching, e.g. plasma etching, e.g. chemical etching, e.g. chemical etching with buffered hydrofluoric acid.

The removal of one or more portions 226, i.e. kerf portions, which include silicon dioxide leaves separated dies 224a, 224b, i.e. chips, on supporting material 242.

One or more portions 226 may even be removed by mechanical sawing, resulting in a reduction or even elimination of crack formation and of chipping compared to mechanical sawing of chemically unchanged SiC. If one or more portions 226 were to be removed by mechanical sawing, one or more portions 226, i.e. the kerf regions for mechanical sawing, may have to be sufficiently wide to accommodated the width of the sawing blade. Inspection of the edges of dies 224a, 224b, e.g. by microscopy, e.g. scanning electron microscopy, shows that chip separation carried out by novel separation approach incurs no sawing damage and no cracks.

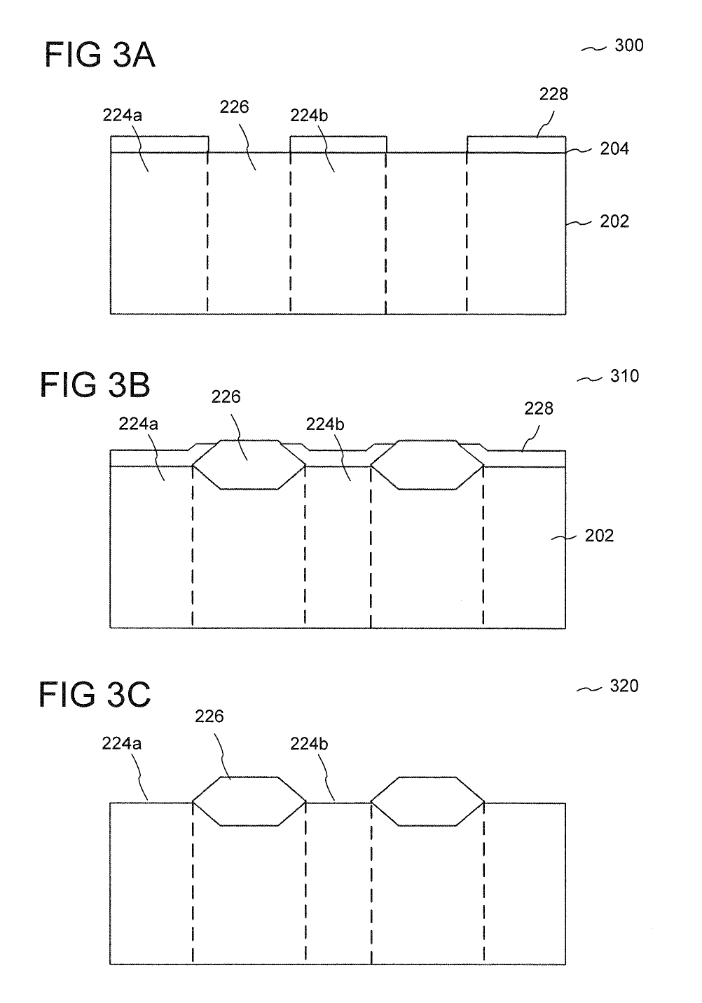

FIGS. 3A to 3B show a method for separating a plurality of dies according to another embodiment. Identical features as to those described with respect to the method of FIGS. 1 and 2A to 2J are denoted with the same reference signs.

Carrier 202 may include silicon. In FIG. 3A, masking layer 228, which may include a silicon nitride layer, may be formed over first carrier side 204. Masking layer 228 may be formed over a first carrier side. Masking layer 228 may be configured to allow the one or more portions 226 to be chemically changed and to shield dies 224a, 224b from being chemically changed.

As with previous embodiments earlier described, the properties of the one or more portions to be removed 226 located between dies 224a, 224b may be chemically changed, whereas dies 224a, 224b may be shielded from being chemically changed. Chemically changing the properties of the one or more portions to be removed 226 may include electrochemically changing the properties of the one or more portions to be removed 226.

However, the one or more portions 226 to be chemically changed may be chemically changed using a local oxidation of silicon LOCOS process. Using a LOCOS process, one or more portions 226 of carrier 202 may be thermally oxidized to form silicon dioxide. The LOCOS process, i.e. thermal oxidation may be carried out from first carrier side 204. According to another embodiment, a separation by implantation of oxygen SIMOX process from first carrier side 204 may be used to chemically change one or more portion 226 from silicon to silicon dioxide.

As shown in FIG. 3B, one or more portions 226 chemically changed to silicon dioxide from a LOCOS process may have a height, e.g. a height ranging from between about 0.1 μm to about 0.5 μm, e.g. about 0.2 μm to about 0.4 μm, extending from first carrier side 204 into carrier 202 towards second carrier side 206. Therefore, as one or more portions 226 chemically changed to silicon dioxide may not extend through a full height of carrier 202 from first carrier side 204 to second carrier side 206 i.e. silicon dioxide is not formed throughout the full height of carrier 202 from first carrier side 204 to second carrier side 206, backside grinding i.e. grinding of second carrier side 206, may be carried out later in the backend process.

In FIG. 3C, mask layer 228 may be removed. A front-end-of-line FEOL process may be performed on at least one die 224a, 224b to form at least one semiconductor device 238, e.g. a diode, e.g. a transistor, e.g. a bipolar junction transistor, e.g. a field effect transistor, e.g. a resistor, e.g. a capacitor, e.g. an inductor, e.g. a thyristor. A front-end-of-line FEOL process includes at least one process used to form the active electrical components of the semiconductor device. A front-end-of-line FEOL process includes performing a front-end-of-line FEOL process on a front side of a semiconductor wafer.

Carrier 202 may be mounted over a support before selectively removing the one or more portions 226 of carrier 202 whose properties were chemically changed for separating the dies 224a, 224b along the removed one or more portions 226.

Carrier 202 may be mounted onto a supporting material 242, such as that described with respect to FIG. 2J. First carrier side 204 may be placed over supporting material 242, such that supporting material 242 may hold carrier 202. Supporting material 242 may hold dies 224a, 224b from a first carrier side 204 when separated. Supporting material 242 may be additionally supported by further supporting material 244, which may include a platform.

One or more portions 226 of carrier 202 whose properties were chemically changed may be selectively removed for separating the dies along the removed one or more portions 226. One or more portions 226 may be selectively removed by etching, e.g. plasma etching, e.g. chemical etching, e.g. chemical etching with buffered hydrofluoric acid.

The removal of one or more portions 226, i.e. kerf portions, which include silicon dioxide leaves separated dies 224a, 224b, i.e. chips, on supporting material 242.

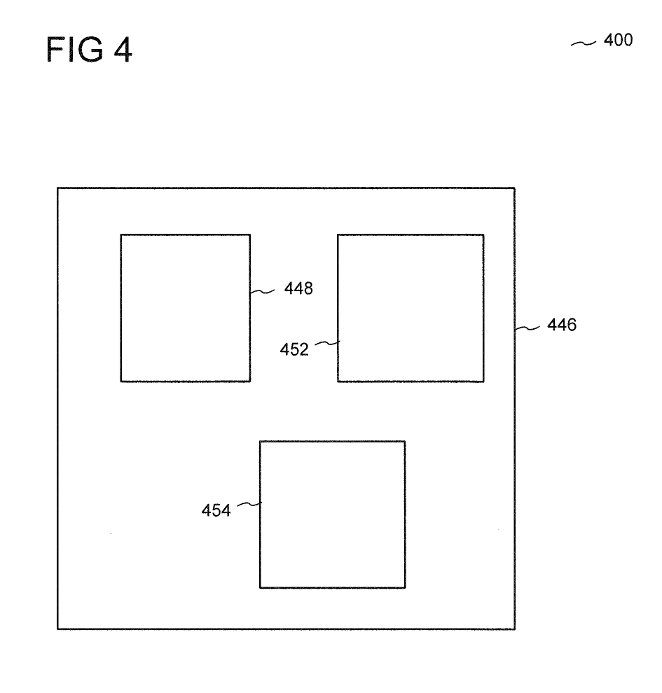

In FIG. 4, a processing device 446 for separating a plurality of dies 224a, 224b is provided. Processing device 446 may include a selection apparatus 448 configured to define one or more portions 226 to be removed from carrier 202 including a plurality of dies 224a, 224b by chemically changing the properties of the one or more portions 226 to be removed located between the dies; process apparatus 452 configured to perform a front-end-of-line FEOL process on at least one die 224a, 224b to form at least one semiconductor device 238; and removal apparatus 454 configured to selectively remove the one or more portions 226 of carrier 202 whose properties were chemically changed for separating the dies 224a, 224b along the removed one or more portions. Selection apparatus 448 may be configured to define one or more portions 226 to be removed from carrier 202 including a plurality of dies 224a, 224b by chemically changing the properties of the one or more portions 226 to be removed located between the dies 224a, 224b, according to the method described with respect to FIGS. 1, 2A to 2J, and 3A to 3C. Process apparatus 452 may be configured to perform a front-end-of-line FEOL process on at least one die 224a, 224b to form at least one semiconductor device 238 according to the method described with respect to FIGS. 1, 2A to 2J, and 3A to 3C. Removal apparatus 454 may be configured to selectively remove the one or more portions 226 of carrier 202 whose properties were chemically changed for separating the dies 224a, 224b along the removed one or more portions according to the method described with respect to FIGS. 1, 2A to 2J, and 3A to 3C.

A method for separating a plurality of dies is provided according to various embodiments. The method may include defining one or more portions to be removed from a carrier including a plurality of dies by chemically changing the properties of the one or more portions to be removed located between the dies; performing a front-end-of-line FEOL process on at least one die to form at least one semiconductor device; and selectively removing the one or more portions of the carrier whose properties were chemically changed for separating the dies along the removed one or more portions.

According to an embodiment, defining one or more portions to be removed from a carrier includes chemically changing the properties of the one or more portions to be removed located between the dies and shielding the dies from being chemically changed.

According to an embodiment, chemically changing the properties of the one or more portions to be removed includes electrochemically changing the properties of the one or more portions to be removed.

According to an embodiment, chemically changing the properties of one or more portions to be removed includes chemically changing the properties of the one or more portions to be removed by an etching process.

According to an embodiment, chemically changing the properties of the one or more portions to be removed includes electrochemically etching the one or more portions to be removed in an electrolyte solution.

According to an embodiment, chemically changing the properties of the one or more portions to be removed includes electrochemically converting the one or more portions to be removed into a porous material.

According to an embodiment, defining one or more portions to be removed from a carrier includes forming at least one layer over a first carrier side and configuring the layer to allow the one or more portions to be chemically changed and to shield the dies from being chemically changed.

According to an embodiment, defining one or more portions to be removed from a carrier includes exposing the one or more portions to an electrolyte solution on a first carrier side and applying a current through the electrolyte solution between an electrode located in the electrolyte solution and a further electrode electrically connected to the one or more portions to be removed via a second carrier side.

According to an embodiment, defining one or more portions to be removed from a carrier includes thermally oxidizing the one or more portions to be removed into an oxide material.

According to an embodiment, defining one or more portions to be removed from a carrier includes chemically changing the one or more portions, each portion extending between a first carrier side and a second carrier side, wherein at least one of the first carrier side and second carrier side includes a front side or back side of a semiconductor wafer.

According to an embodiment, defining one or more portions to be removed from a carrier includes chemically changing the one or more portions, each portion extending through a full height of the carrier from a first carrier side to a second carrier side, wherein at least one of the first carrier side and second carrier side includes a front side or back side of a semiconductor wafer.

According to an embodiment, performing a front-end-of-line FEOL process on at least one die to form at least one semiconductor device includes performing a front-end-of-line FEOL process on at least one die to form at least part of at least one device from the following group of devices, the group consisting of: a diode, a transistor, a bipolar junction transistor, a field effect transistor, a resistor, a capacitor, and inductor and a thyristor.

According to an embodiment, performing a front-end-of-line FEOL process on at least one die to form at least one semiconductor device includes at least one process used to form the active electrical components of the semiconductor device.

According to an embodiment, performing a front-end-of-line FEOL process on at least one die to form at least one semiconductor device includes performing a front-end-of-line FEOL process on a front side of a semiconductor wafer.

According to an embodiment, the method further includes mounting the carrier over a support before selectively removing the one or more portions of the carrier whose properties were chemically changed for separating the dies along the removed one or more portions.

According to an embodiment, selectively removing the one or more portions of the carrier whose properties were chemically changed includes selectively removing the one or more portions of the carrier by chemical etching.

According to an embodiment, selectively removing the one or more portions of the carrier whose properties were chemically changed includes selectively removing the one or more portions of the carrier by plasma etching.

According to an embodiment, defining one or more portions to be removed from a carrier including a plurality of dies includes defining one or more portions to be removed from a carrier including at least one material from the following group of materials, the group consisting of: silicon and silicon carbide.

A processing device for separating a plurality of dies is provided. The processing device may include a selection apparatus configured to define one or more portions to be removed from a carrier including a plurality of dies by chemically changing the properties of the one or more portions to be removed located between the dies; a process apparatus configured to perform a front-end-of-line FEOL process on at least one die to form at least one semiconductor device; and a removal apparatus configured to selectively remove the one or more portions of the carrier whose properties were chemically changed for separating the dies along the removed one or more portions.

Various embodiments provide a process for chip separation of dies, e.g. silicon carbide dies and an alternative to plasma dicing and mechanical sawing for damage-free separation of dies, e.g. silicon carbide dies, from a wafer.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A method for separating a plurality of dies, the method comprising:
defining one or more portions to be removed from a carrier comprising a plurality of dies by chemically changing the properties of the one or more portions to be removed located between the dies;
performing a front-end-of-line FEOL process on at least one die to form at least one semiconductor device; and
selectively removing the one or more portions of the carrier whose properties were chemically changed for separating the dies along the removed one or more portions.

2. The method according to claim 1, wherein defining one or more portions to be removed from a carrier comprises chemically changing the properties of the one or more portions to be removed located between the dies and shielding the dies from being chemically changed.

3. The method according to claim 1, wherein chemically changing the properties of the one or more portions to be removed comprises electrochemically changing the properties of the one or more portions to be removed.

4. The method according to claim 1, wherein chemically changing the properties of one or more portions to be removed comprises chemically changing the properties of the one or more portions to be removed by an etching process.

5. The method according to claim 1, wherein chemically changing the properties of the one or more portions to be removed comprises electrochemically etching the one or more portions to be removed in an electrolyte solution.

6. The method according to claim 1, wherein chemically changing the properties of the one or more portions to be removed comprises electrochemically converting the one or more portions to be removed into a porous material.

7. The method according to claim 1, wherein defining one or more portions to be removed from a carrier comprises forming at least one layer over a first carrier side and configuring the layer to allow the one or more portions to be chemically changed and to shield the dies from being chemically changed.

8. The method according to claim 1, wherein defining one or more portions to be removed from a carrier comprises exposing the one or more portions to an electrolyte solution on a first carrier side and applying a current through the electrolyte solution between an electrode located in the electrolyte solution and a further electrode electrically connected to the one or more portions to be removed via a second carrier side.

9. The method according to claim 1, wherein defining one or more portions to be removed from a carrier comprises thermally oxidizing the one or more portions to be removed into an oxide material.

10. The method according to claim 1, wherein defining one or more portions to be removed from a carrier comprises chemically changing the one or more portions, each portion extending between a first carrier side and a second carrier side, wherein at least one of the first carrier side and second carrier side comprises a front side or back side of a semiconductor wafer.

11. The method according to claim 1, wherein defining one or more portions to be removed from a carrier comprises chemically changing the one or more portions, each portion extending through a full height of the carrier from a first carrier side to a second carrier side, wherein at least one of the first carrier side and second carrier side comprises a front side or back side of a semiconductor wafer.

12. The method according to claim 1, wherein performing a front-end-of-line FEOL process on at least one die to form at least one semiconductor device comprises performing a front-end-of-line FEOL process on at least one die to form at least part of at least one device from the following group of devices, the group consisting of: a diode, a transistor, a bipolar junction transistor, a field effect transistor, a resistor, a capacitor, and inductor and a thyristor.

13. The method according to claim 1, wherein performing a front-end-of-line FEOL process on at least one die to form at least one semiconductor device comprises at least one process used to form the active electrical components of the semiconductor device.

14. The method according to claim 1, wherein performing a front-end-of-line FEOL process on at least one die to form at least one semiconductor device comprises performing a front-end-of-line FEOL process on a front side of a semiconductor wafer.

15. The method according to claim 1, wherein the method further comprises mounting the carrier over a support before selectively removing the one or more portions of the carrier whose properties were chemically changed for separating the dies along the removed one or more portions.

16. The method according to claim 1, wherein selectively removing the one or more portions of the carrier whose properties were chemically changed comprises selectively removing the one or more portions of the carrier by chemical etching.

17. The method according to claim 1, wherein selectively removing the one or more portions of the carrier whose properties were chemically changed comprises selectively removing the one or more portions of the carrier by plasma etching.

18. The method according to claim 1, wherein defining one or more portions to be removed from a carrier comprising a plurality of dies comprises defining one or more portions to be removed from a carrier comprising at least one material from the following group of materials, the group consisting of: silicon and silicon carbide.

19. A processing device for separating a plurality of dies, the processing device comprising:
a selection apparatus configured to define one or more portions to be removed from a carrier comprising a plurality of dies by chemically changing the properties of the one or more portions to be removed located between the dies;
a process apparatus configured to perform a front-end-of-line FEOL process on at least one die to form at least one semiconductor device; and
a removal apparatus configured to selectively remove the one or more portions of the carrier whose properties were chemically changed for separating the dies along the removed one or more portions.
